(19) United States
(12) Patent Application Publication
(10) Pub. No.: US 2009/0189631 A1
(43) Pub. Date: Jul. 30, 2009

(54) MOVEMENT APPARATUS AND ELECTRONIC DEVICE TEST APPARATUS

(75) Inventors: Kenichi Shimada, Tokyo (JP); Yoshiyuki Masuo, Tokyo (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 12/280,757

(22) PCT Filed: Feb. 21, 2007
(86) PCT No.: PCT/JP2007/053179

§ 371 Date: Aug. 26, 2008

(30) Foreign Application Priority Data
Mar. 2, 2006 (JP) 2006-056712

(51) Int. Cl. G01R 31/26

(52) U.S. Cl. 324/765

(57) ABSTRACT

An air cylinder raising and lowering a pickup head for holding an IC device in an electronic device test apparatus, the air cylinder includes a cylinder tube; a piston; a first hollow chamber formed below the piston; a second hollow chamber formed above the piston and being larger than the first hollow chamber in terms of a pressure receiving area of the piston; and a rod with one end coupled with the piston and the other end coupled with the pickup head. The first hollow chamber is connected to the air feed device via a first feed system in which the air feed is secured even if the electric power supply of the electronic device test apparatus is cut off, and the second hollow chamber is connected to the air feed device via a second feed system having a shutoff valve.

### TECHNICAL FIELD

The present invention relates to a movement apparatus for moving a pickup head, a shutter or other components in an electronic device test apparatus which tests semiconductor integrated circuit devices and other various types of electronic devices (hereinafter, also referred to representatively as “IC devices”) for electrical characteristics, and an electronic device test apparatus using the same.

### BACKGROUND ART

In an IC test apparatus (electronic device test apparatus) called a “handler”, a large number of IC devices held on a tray are conveyed into the handler, each of the IC devices is then brought into electrical contact with a test head and the electronic device test apparatus body (hereinafter, also referred to as a “tester”) executes test. Furthermore, when the testing is finished, each of the IC devices is ejected from the test head and reloaded on trays in accordance with the test results so as to classify them into categories such as good devices and defective devices.

In such an electronic device test apparatus, there is a type in which the trays for holding pre-test ICs or holding post-test ICs (hereinafter, also referred to as “customer trays”) and the trays circulated inside the electronic device test apparatus (hereinafter, also referred to as “test trays”) are different. In this type of electronic device test apparatus, an IC conveyance system reloads ICs between the customer trays and the test trays before and after the tests.

In this IC conveyance system, a pickup head which hold IC device by suction can move three-dimensionally, and an air cylinder or a servo motor etc. is used for the drive unit. Also an air cylinder or a servo motor etc. is used for the elevator mechanisms for moving the pickup head along the vertical direction (Z-axial direction).

Furthermore, when power outages or emergencies result in the power being cut off, the pickup head descends by its own weight in the vertical downward direction and are liable to strike the apparatus base board or other structures etc. and be damaged. For this reason, the elevator mechanism is provided with a spring for holding the pickup head, a brake mechanism for the motor, or other safety devices in addition to the air cylinder or the servo motor etc.

However, when providing the spring, the brake mechanism, and other safety devices at the elevator mechanism besides the air cylinder and the motor, there is the problem that the elevator mechanism become large in size.

### DISCLOSURE OF THE INVENTION

The present invention has as its object the provision of a movement apparatus enabling a reduction of size by eliminating the need of a special safety device for dealing with power cutoffs at the time of power outages and emergencies.

To achieve the above object, according to the present invention, there is provided a movement apparatus for moving a member, the movement apparatus comprising a fluid pressure cylinder having: a cylinder tube; a piston inserted inside the cylinder tube in a movable manner; a first hollow chamber formed at one side of the piston; a second hollow chamber formed at the other side of the piston and being larger than the first hollow chamber in terms of a pressure receiving area of the piston; and a rod with one end coupled with the piston and another end coupled with the member, wherein the first hollow chamber is connected to a fluid feed source via a first feed system able to constantly secure a fluid feed of fluid from the fluid feed source, and the second hollow chamber is connected to the fluid feed source via a second feed system having a shutoff valve able to open and close a channel (see claim 1).

In the present invention, the second hollow chamber is larger than the first hollow chamber in terms of the pressure receiving area of the piston in the fluid pressure cylinder of the movement apparatus, the first hollow chamber is connected to the first feed system able to constantly secure the fluid feed from the fluid feed source, and the second hollow chamber is connected to the second feed system having a shutoff valve able to open and close the channel.

At the time of ordinary use, when opening the shutoff valve of the second feed system, the piston moves to the first hollow chamber side by the difference in the pressure receiving areas of the piston which receive pressure from the first and second hollow chambers. On the other hand, when closing the shutoff valve of the second feed system, the piston is pushed so as to move to the second hollow chamber side.

Further, for example even if the shutoff valve is closed at the time of a power outage or emergency and no fluid is fed via the second feed system to the second hollow chamber, fluid is fed to the first feed system and the piston is constantly pushed to the second hollow chamber side. By utilizing this as a safety device for dealing with power cutoffs at the time of power outage or emergencies, it is possible to reduce the size of the movement apparatus.

While not particularly limited in the invention, the first feed system preferably has a regulating means able to regulate the flow rate or pressure of the fluid (see claim 2). Due to this, the thrust of the piston can be suitably adjusted.

While not particularly limited in the invention, preferably the moving means is provided in an electronic device test apparatus for testing device under test for electrical characteristic, the first feed system is able to ensure the fluid feed from the fluid feed source even when an electric power supply of the electronic device test apparatus is cut off, and the shutoff valve of the second feed system includes a solenoid valve which drives by electric power fed from the electric power supply and closes the second feed system when the electric power supply is cut off (see claim 3).

While not particularly limited in the invention, preferably the rod passes through the first hollow chamber and is coupled with the member at its other end (see claim 4).

While not particularly limited in the invention, preferably the member is a holder for holding a device under test by suction (see claim 5).

While not particularly limited in the invention, preferably the member is a shutter for opening and closing a conveyance path inside the chamber or an opening part (see claim 6).

While not particularly limited in the invention, preferably the piston is inserted inside the cylinder tube so as to be able to move along the vertical direction, the first hollow chamber is formed above or below the piston, and the second hollow chamber is formed below or above the piston (see claim 7).

Further, to achieve the above object, according to the present invention, there is provided an electronic device test apparatus for bringing input/output terminals of device under test into contact with a contact part of the test head to test the device under test for electrical characteristic, the electronic device test apparatus comprising a movement apparatus as set forth in any one of the above (see claim 8).

### BRIEF DESCRIPTION OF THE DRAWINGS

FIG. 1 is a schematic side view showing an electronic device test apparatus according to an embodiment of the present invention.

FIG. 2 is a perspective view showing an electronic device test apparatus according to an embodiment of the present invention.

FIG. 3 is a conceptual view showing the routing of a tray in an electronic device test apparatus according to an embodiment of the present invention.

FIG. 4 is a schematic view showing an IC stocker used in an electronic device test apparatus according to an embodiment of the present invention.

FIG. 5 is a perspective view showing a customer tray used in an electronic device test apparatus according to an embodiment of the present invention.

FIG. 6 is a side view showing a movable head of an XY conveyance system in an embodiment of the present invention.

FIG. 7 is a sectional view of an air cylinder of a movable head shown in FIG. 6 and a block diagram of an air feed system.

FIG. 8 is a sectional view along the line VIII-VIII of FIG. 7.

FIG. 9 is a sectional view along the line IX-IX of FIG. 7.

FIG. 10 is a disassembled perspective view showing a test tray used in an electronic device test apparatus according to an embodiment of the present invention.

FIG. 11A is a schematic sectional view showing a shutter provided in a tray conveyance path between a test chamber and an unsoak chamber in an electronic device test apparatus according to an embodiment of the present invention and shows the state with the shutter closing the tray conveyance path.

FIG. 11B is a schematic sectional view showing a shutter provided in a tray conveyance path between a test chamber and an unsoak chamber in an electronic device test apparatus according to an embodiment of the present invention and shows the state where the shutter opens the tray conveyance path.

FIG. 12A is a schematic sectional view showing a shutter provided at an entrance of a soak chamber in an electronic device test apparatus according to an embodiment of the present invention and shows the state where the shutter closes the entrance side opening.

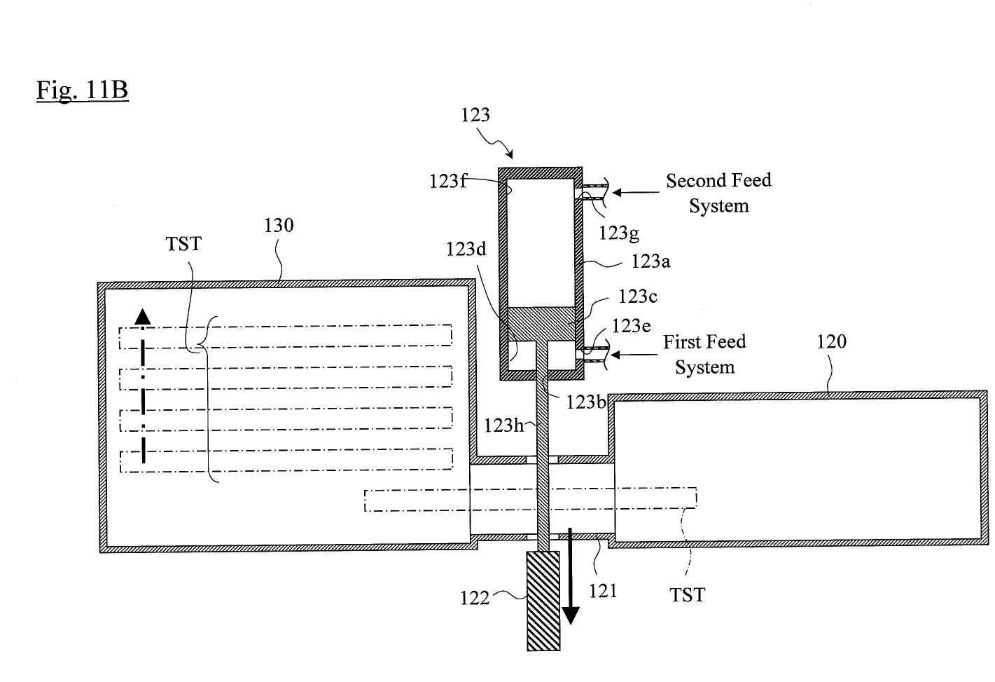

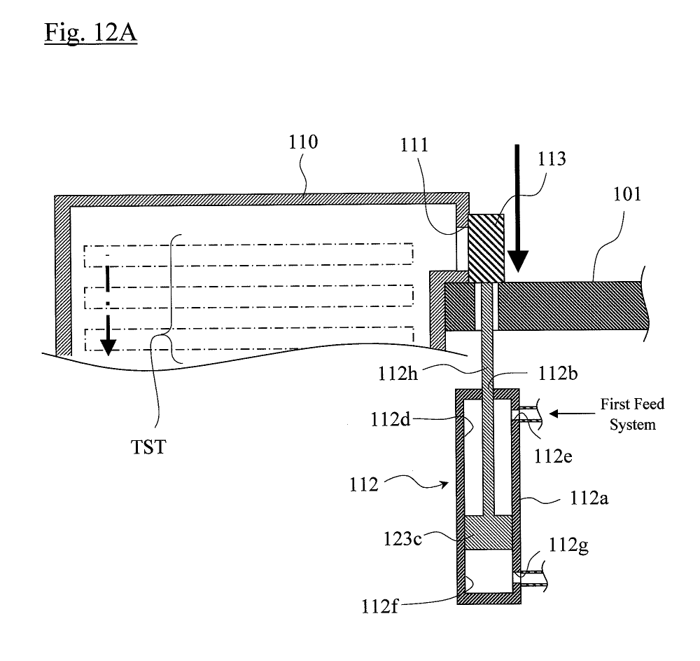

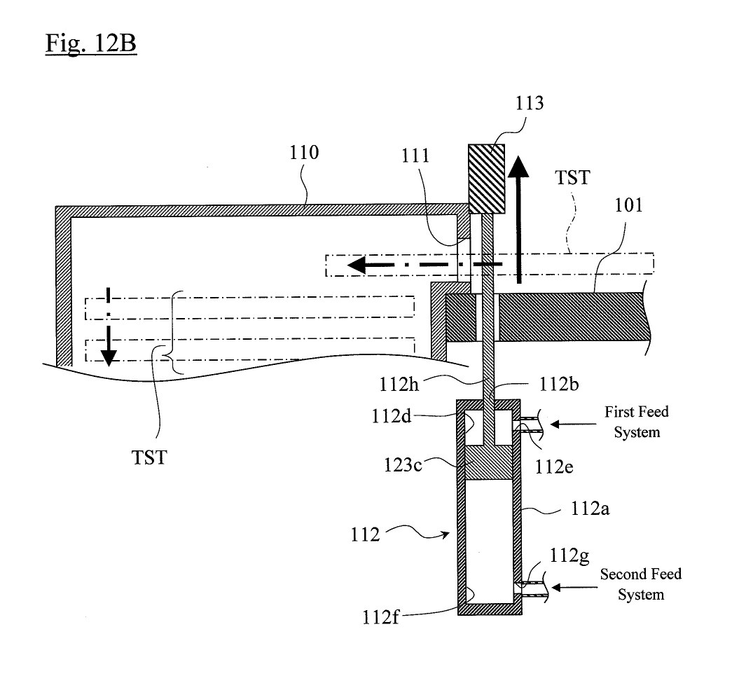

[FIG. 12B] FIG. 11B is a schematic sectional view showing a shutter provided at an entrance of a soak chamber in an electronic device test apparatus according to an embodiment of the present invention and shows the state where the shutter opens the entrance side opening.

### DESCRIPTION OF NOTATIONS

1 . . . handler
100 . . . chamber unit
110 . . . soak chamber
111 . . . entrance
112 . . . air cylinder
113 . . . shutter
120 . . . test chamber
121 . . . tray conveyance path
122 . . . shutter
123 . . . air cylinder
130 . . . unsoak chamber
200 . . . storage unit
300 . . . loader unit
301 . . . rail
302 . . . movable arm
303 . . . movable head
303a . . . first base member
303b . . . X-axial direction linear guide
303c . . . second base member
303d . . . Z-axial direction linear guide
303e . . . pickup head
303f . . . coupling member
303g . . . suction pad
304 . . . XY conveyance system
305 . . . air cylinder
305a . . . cylinder tube
305c . . . piston
305d . . . first hollow chamber
305f . . . second hollow chamber
305h . . . rod
306 . . . first air feed system
307 . . . second air feed system
400 . . . unloader unit

### BEST MODE FOR CARRYING OUT THE INVENTION

Below, an embodiment of the present invention will be explained based on the drawings.

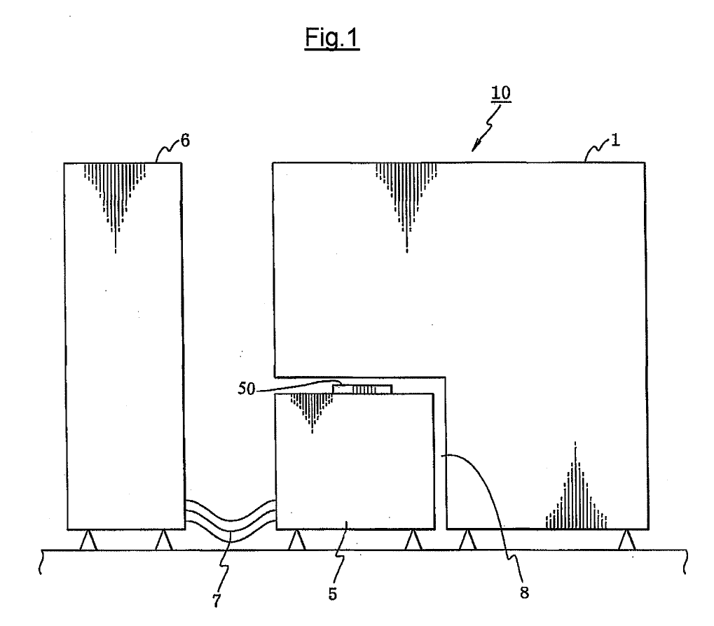

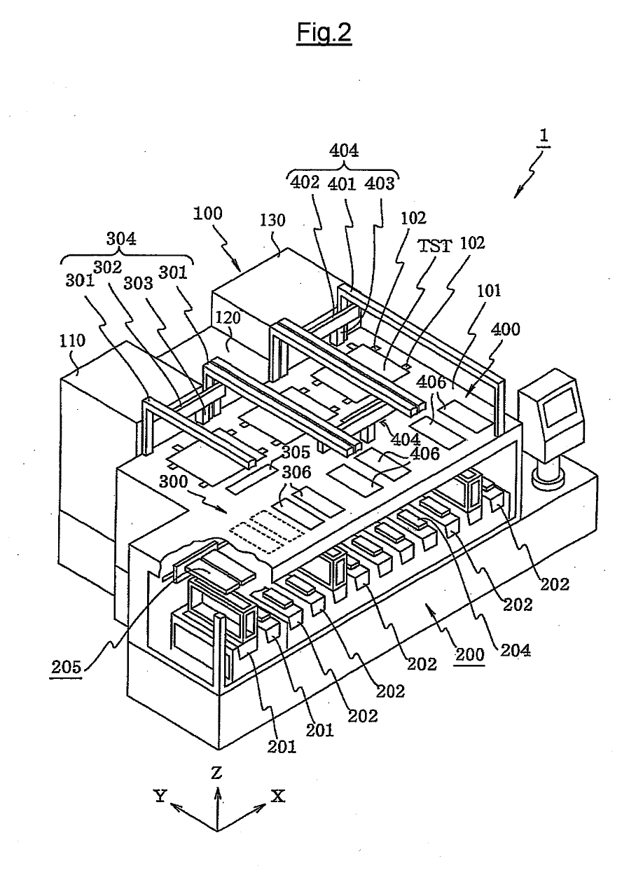

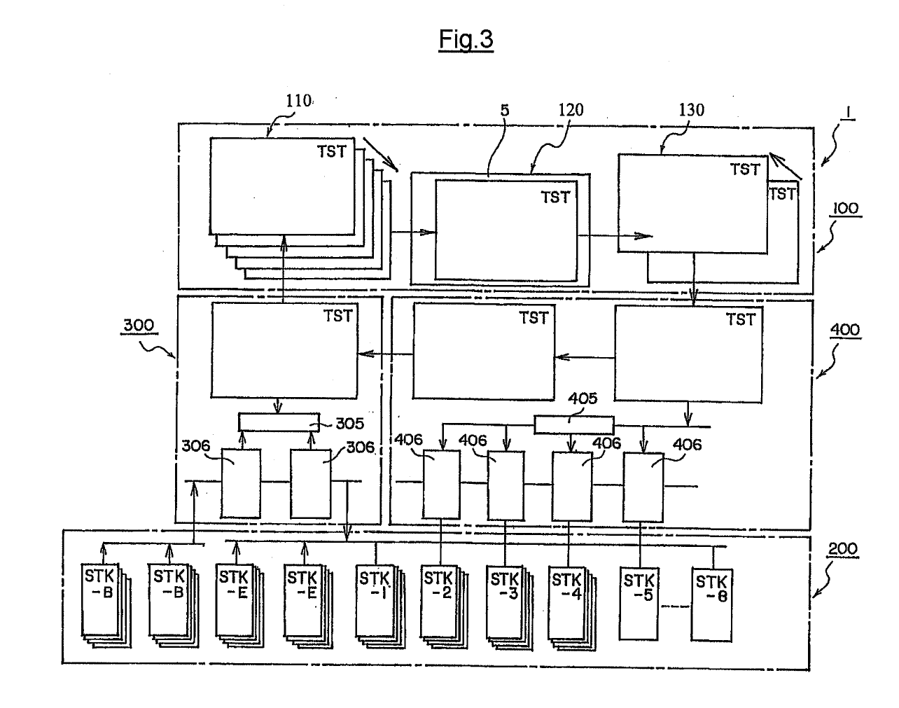

FIG. 1 is a schematic cross-sectional view showing an electronic device test apparatus according to an embodiment of the present invention, FIG. 2 is a perspective view showing an electronic device test apparatus according to an embodiment of the present invention, and FIG. 3 is a conceptual view showing the routing of a tray in an electronic device test apparatus according to an embodiment of the present invention.

Note that FIG. 3 is a view for understanding the method of routing a tray in an electronic device test apparatus according to an embodiment of the present invention. A part of members actually arranged aligned in the vertical direction are shown planarly. Therefore, the mechanical (3D) structure will be explained while referring to FIG. 2.

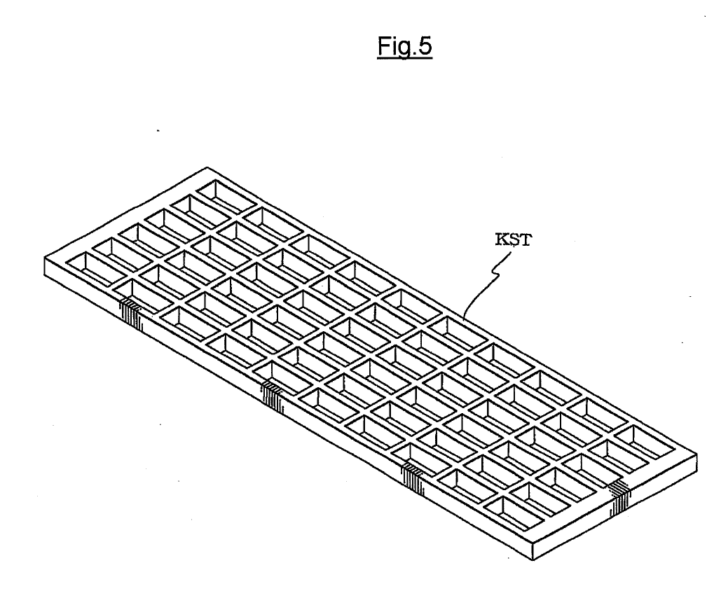

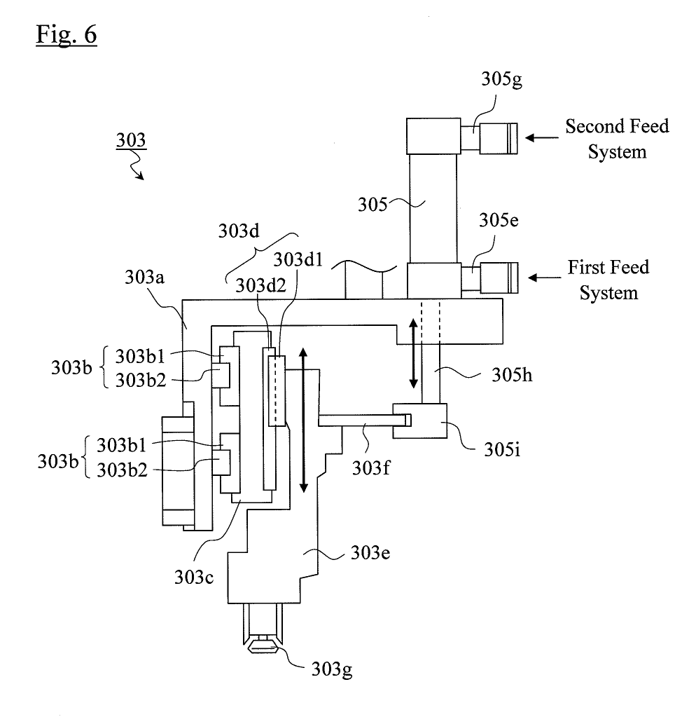

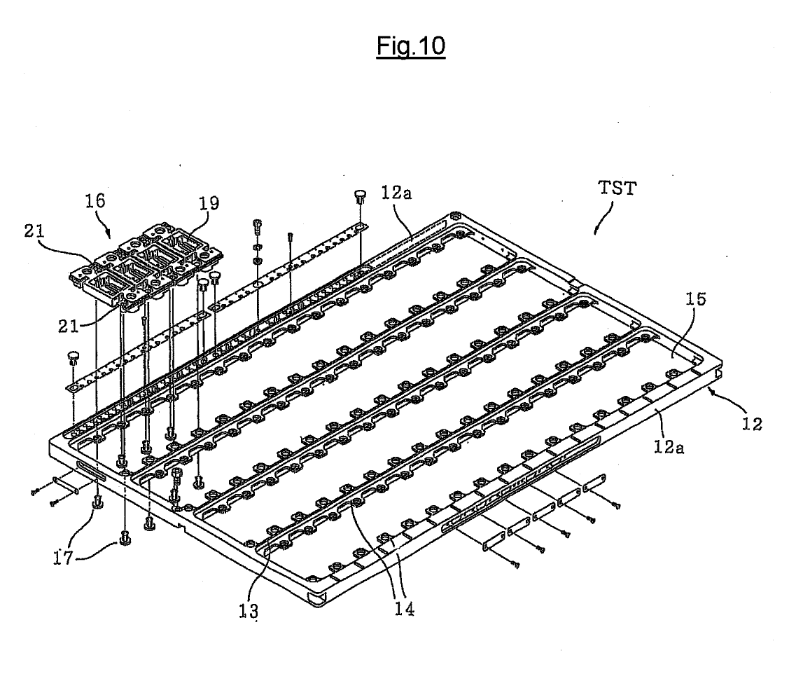

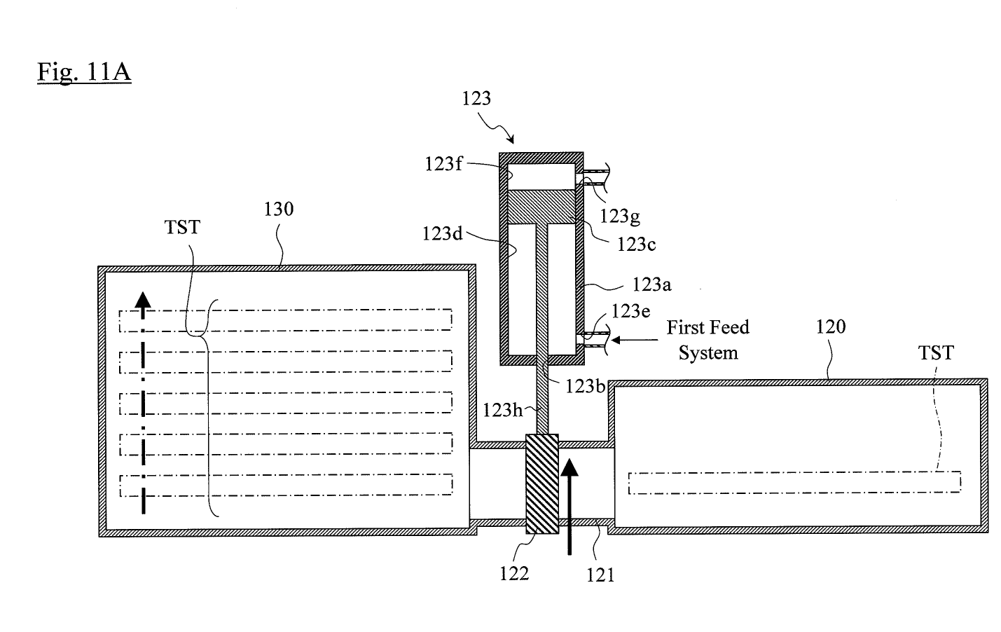

The electronic device test apparatus according to the present embodiment is a apparatus which tests (inspects) whether an IC device is suitably operating in the state where the IC device is given a high temperature or low temperature thermal stress and classifies the IC device based on the test results and comprises a handler 1, a test head 5, and a tester 9. IC devices are tested by this electronic device test apparatus after reloading the IC devices from a tray on which a large number of the IC devices under test are mounted (hereinafter, also referred to as a “customer tray”, see FIG. 5) to a tray to be conveyed into the handler 1 (hereinafter, also referred to as a “test tray”, see FIG. 10).

For this reason, the handler 1 in the present embodiment, as shown in FIG. 1 to FIG. 3, comprises a storage unit 200 for storing IC devices to be tested from then on or storing finished tested IC devices classified, a loader unit 300 for transferring IC devices sent from the storage unit 200 to a chamber unit 100, a chamber unit 100 including a test head 5, and an unloader unit 400 for classifying and taking out the tested IC devices tested in the chamber unit 100.

Sockets 50 provided at the test head 5 are connected to the tester 6 via cables 7 shown in FIG. 1, the IC devices electrically connected to the sockets 50 are connected to the tester 6 via the cables 7, and the IC devices are tested by test signals from that tester 6. Note that as shown in FIG. 1, the handler 1 is provided with a space at part of the bottom. In this space, the test head 5 is interchangeably arranged. Through holes formed in the apparatus base board of the handler 1, the IC devices and sockets 50 on the test head 5 can be brought into electrical contact. When changing the type of IC devices, the test head is changed to another test head having sockets suitable for the shape and the number of pins of that type of IC devices.

Below, the parts of the handler 1 will be explained in detail.

<Storage Unit 200>

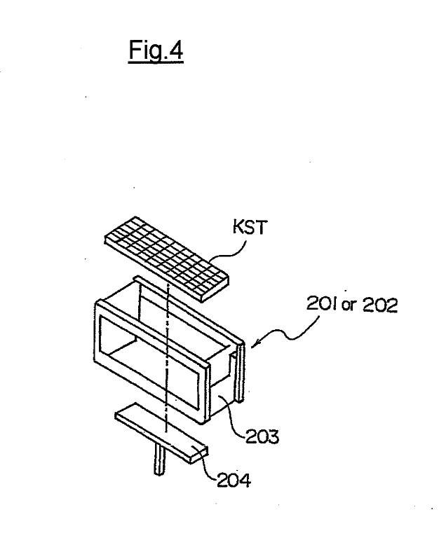

FIG. 4 is a disassembled perspective view showing an IC stocker used in an electronic device test apparatus according to an embodiment of the present invention, while FIG. 5 is a perspective view showing a customer tray used in an electronic device test apparatus according to an embodiment of the present invention.

The storage unit 200 comprises pre-test IC stockers 201 for storing pre-test IC devices and post-test IC stockers 202 for storing IC devices classified in accordance with the test results.

Each of these stockers 201 and 202, as shown in FIG. 4, comprises a frame-shaped tray support frame 203 and an elevator 204 entering from the bottom of the tray support frame 203 and rising upward. A plurality of customer trays KST are stacked in each tray support frame 203. Only these stacked customer trays KST are moved up and down by the elevator 204. Note that a customer tray KST in the present embodiment, as shown in FIG. 5, has holders for holding IC devices arranged in 10 rows and 6 columns.

In the present embodiment, as shown in FIG. 2 and FIG. 3, two stockers STK-B are provided as the pre-test IC stockers 201. Next to them, two empty tray stockers STK-E in which empty customer trays KST send to the unloader unit 400 are stacked. Next to the empty tray stockers STK-E, eight stockers STK-1, STK-2, . . . , STK-8 are provided as the post-test IC stockers 202. It is therefore possible to store the devices classified into as many as eight categories in accordance with the test results. That is, in addition to good and defective devices, it is possible to classify good devices into ones with operating speeds which are high, medium, and low or defective ones where retesting is required.

<Loader Unit 300>

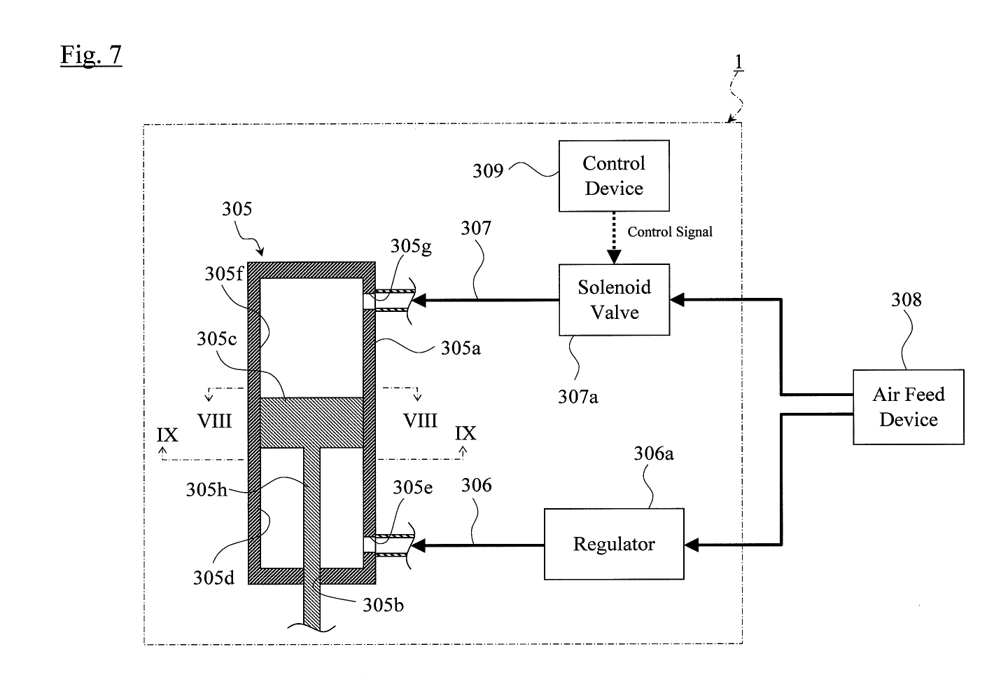

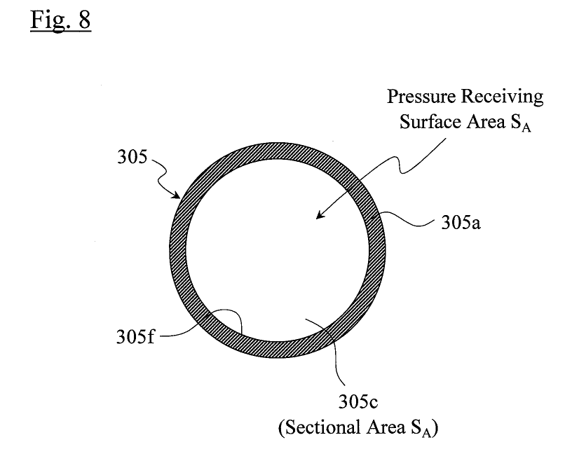

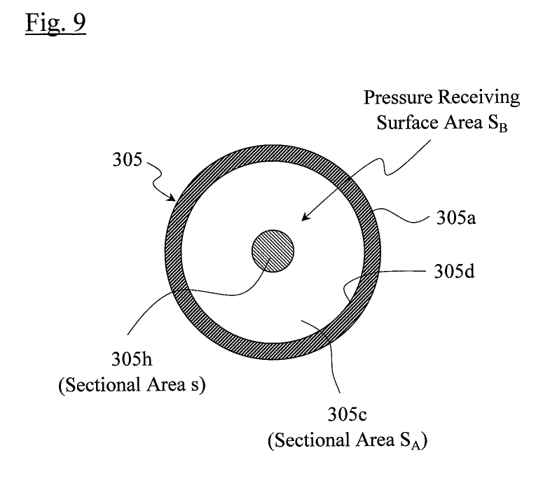

FIG. 6 is a side view showing a movable head of a conveyance system in an embodiment of the present invention, FIG. 7 is a sectional view of an air cylinder of a movable head shown in FIG. 6 and a block diagram of an air feed system, FIG. 8 is a sectional view along line VIII-VIII of FIG. 7, FIG. 9 is a sectional view along line IX-IX of FIG. 7, and FIG. 10 is a disassembled perspective view showing a test tray used in an electronic device test apparatus according to an embodiment of the present invention.

The above-mentioned customer tray KST is conveyed from below the apparatus base board 101 to windows 306 of the loader unit 300 by a tray transfer arm 205 provided between the storage unit 200 and the apparatus base board 101. Further, the XY conveyance system 304 transports IC devices loaded on the customer tray KST to a preciser 305 once. After correcting the positional relationships between the IC devices there, the IC devices transported to this preciser 305 are again reloaded by the XY conveyance system 304 to a test tray TST stopped at the loader unit 300.

The XY conveyance system 304 reloading IC devices from a customer tray KST to a test tray TST, as shown in FIG. 2, comprises two rails 301 provided on the apparatus base board 101, a movable arm 302 able to move back and forth between the test tray TST and the customer tray KST by the two rails 301 (this direction referred to as the “Y-direction”), and a movable head 303 supported by this movable arm 302 and able to move along the movable arm 302 in the X-axial direction.

The movable head 303, as shown in FIG. 6, comprises a first base member 303a, X-axial direction linear guides 303b, a second base member 303c, Z-axial direction linear guides 303d, a pickup head 303e, and an air cylinder 305.

The first base member 303a has a substantially L-shaped cross-sectional shape and is attached to the movable arm 302 at its top. Guide rails 303b2 of the X-axial direction linear guides 303b are provided along the X-axial direction at the inside surface of the downward projecting part of the first base member 303a.

Guide tables 303b1 of the X-axial direction linear guides 303b are provided at the main surface facing the first base member 303a in the second base member 303c. These guide tables 303b1 are guided by the guide rails 303b2 provided at the first base member 303a whereby the second base member 303c moves with respect to the first base member 303a along the X-axial direction. Further a guide rail 303d2 of a Z-axial direction linear guide 303d is provided at the other main surface of the second base member 303c.

A guide table 303d1 of the Z-axial direction linear guide 303d is provided at the upper side surface of the pickup head 303e. This guide table 303d1 is guided by the guide rail 303d2 provided at the second base member 303c whereby the pickup head 303e moves with respect to the second base member 303c along the Z-axial direction. A suction pad 303g for holding an IC device by suction is attached downward at the bottom of the pickup head 303e.

An air cylinder 305 is provided at the end of the top surface of the first base member 303a in a posture with a rod 305h facing the downward direction. A linear guide 305i allowing movement along the X-axial direction is provided at the front end of the air cylinder 305. A coupling member 303f projecting from the pickup head 303e toward the rod 305h is supported by the linear guide 305i so as to be able to move along the X-axial direction. By the air cylinder 305 moving up and down, the pickup head 303e can move relatively up and down with respect to the second base member 303c.

The air cylinder 305 provided in this movable head 303 is a double acting single rod type air pressure cylinder and, as shown in FIG. 6, is arranged so that the rod 305b faces the downward direction. This air cylinder 305, as shown in FIG. 7, comprises a cylindrically shaped cylinder tube 305a, a piston 305c inserted inside this cylinder tube 305a so as to be able to move along with vertical direction, a first hollow chamber 305d formed below the piston 305c, a second hollow chamber 305f formed above the piston 305c, and a rod 305h with one end coupled with the piston 305c and running through the first hollow chamber 305d and a through hole 305b formed at the cylinder tube 305a.

The first hollow chamber 305d is connected to an air feed device 308 provided at the outside of the handler 1 via a first feed system 306 connected to a first port 305e. This first feed system 306 is not provided with any elements cutting off the feed system (for example, a solenoid valve etc.) when the electric power supply of the handler 1 is cut off. For this reason, even when turning off the electric power supply of the handler 1, the air feed from the air feed device 308 to the first hollow chamber 305d of the air cylinder 305 is secured.

On the other hand, the second hollow chamber 305f is connected to an air feed device 308 via a second feed system 307 connected to a second port 305g. This first feed system 307 is provided with a solenoid valve 307a for turning the air feed on/off. The solenoid valve 307a is controlled to open and close by a control device 309 of the handler 1. When the electric power supply of the handler 1 is turned off, the air feed to the second hollow chamber 305f is stopped. Note that the means for turning the air feed on/off in the second feed system 307 is not particularly limited to a solenoid valve 307a in the present invention. For example, it may be a valve utilizing a mechanical system or an air motor.

When raising the pickup head 303e in the movable head 303 using the air cylinder 305 of the above configuration, the solenoid valve 307a is closed and the air feed via the second feed system 307 to the second hollow chamber 305f is stopped. At this time, air is being constantly fed via the first feed system 306 to the first hollow chamber 305d, so the piston 305c rises inside the cylinder tube 305a. Along with this, the pickup head 303e rises.

On the other hand, when lowering the pickup head 303e, the solenoid valve 307a is opened and air is fed from the air feed device 308 to the second hollow chamber 305f via the second feed system 307. At this time, when the pressures of the air fed to the first and second hollow chambers 305d and 305f are substantially the same, as shown in FIG. 8 and FIG. 9, the piston 305c descends inside the cylinder tube 305a by the difference between the pressure receiving area of the piston 305 in the first hollow chamber 305d and the pressure receiving area of the piston 305c in the second hollow chamber 305f. Along with this, the pickup head 303e descends.

That is, if the area of the top face of the piston 305c is S_{A}, since the rod 303h extends downward in the present embodiment, the area of the bottom face of the piston 305c is S_{B} which the sectional area (s) of the rod 305h subtracted from S_{A} gives (S_{B}=S_{A}−s), and the pressure receiving area S_{B} of the piston 305c in the second hollow chamber 305f is relatively smaller than the pressure receiving area S_{A} of the piston 305c in the first hollow chamber 305d (S_{A}>S_{B}). For this reason, when air of substantially the same pressures (P) is fed to the first hollow chamber 305d and the second hollow chamber 305f, the force in the second hollow chamber 305f becomes stronger (F_{A}=S_{A}×P>S_{B}×P=F_{B}) by exactly the area difference S_{A}−S_{B}, so the piston 305c descends inside the cylinder tube 305a. Along with this, the pickup head 303e descends.

In general, the thrust of the air cylinder is unambiguously determined by the cylinder diameter or the pressure of the air etc., but in the present embodiment, as explained above, the difference in pressure receiving areas is utilized, so a small thrust can be obtained and IC devices susceptible to impact can be easily prevented from damage.

Furthermore, in the present embodiment, even when the electric power supply of the handler 1 is turned off, air is fed from the air feed device 308 to the first hollow chamber 305d via the first feed system 306. On the other hand, along with the electric power supply of the handler 1 being turned off, the solenoid valve 307a closes, so the air feed to the second hollow chamber 305f via the second feed system 307 is stopped. For this reason, for example, even when the electric power supply of the handler 1 is turned off at the time of a power outage or emergency, the piston 305c automatically rises due to the pressure of the first hollow chamber 305d, so the pickup head 303e can be prevented from striking the apparatus base board 101 or another structure and being damaged.

The first feed system 306 is provided with a regulator 306a for regulating the pressure of the air. This regulator 306a may be used to regulate the pressure of the air fed to the first hollow chamber 305d so as to regulate the thrust of the piston 305c. To deal with a cutoff of electric power supply at the time of a power outage or emergency, it is sufficient to secure a pressure of an extent enabling the piston 305c's own weight to be supported. This can be determined by considering the impact load etc. given to the IC device.

Note that the regulator 306a is not controlled by the control device 309 of the handler 1. Even when the electric power supply of the handler 1 is cut off, the path of air feed is never cut off. Further, in the present invention, instead of the regulator, it is possible to provide a speed controller for regulating the flow rate of air in the first feed system.

In the present embodiment, eight movable heads 303 configured in the above way are attached. It is therefore possible to reload eight IC devices at a time from a customer tray KST to a test tray TST.

FIG. 10 is a perspective view showing a test tray TST used in the present embodiment. The test tray TST comprises a rectangular frame 12 at which a plurality of beams 13 are provided in parallel at equal intervals. At the both sides of the beams 13 and the sides of the frames 12 facing the beams 13, pluralities of mounting pieces 14 are formed sticking out at equal intervals. Insert holders 15 are formed by these beams 13 and two mounting pieces 703 or by the beams 13, sides 12a and two mounting pieces 703.

Each insert holder 15 is designed to accommodate a single insert 16. This insert 16 is attached in a floating state to the two mounting pieces 14 using fasteners 17. For this reason, mounting holes 21 for the mounting pieces 14 are formed at the both ends of each insert 710. 16×4 or so of these inserts 710 are mounted on a single test tray TST.

Note that the inserts 16 have the same shape and the same dimensions and each of the inserts 16 holds an IC device. The IC holders 19 of the inserts 16 are determined in accordance with the shape of the IC devices held. In the example shown in FIG. 10, they are rectangular recesses.

<Chamber Unit 100>

FIG. 11A and FIG. 11B are schematic sectional views showing a shutter provided in the tray conveyance path between the test chamber and the unsoak chamber in an electronic device test apparatus according to an embodiment of the present invention, where FIG. 11A is a view showing the state where the shutter closes the tray conveyance path while FIG. 11B is a view showing the state where the shutter opens the tray conveyance path, while FIG. 12A and FIG. 12B are schematic sectional views showing a shutter provided at the entrance of the soak chamber in an electronic device test apparatus according to an embodiment of the present invention, where FIG. 12A is a view showing the state where the shutter closes the entrance, while FIG. 12B is a view showing the state where the shutter opens the entrance opening.

The above-mentioned test tray TST is loaded with IC devices in the loader unit 300, then is sent into the chamber unit 100 where the IC devices are tested in the state with the IC devices carried on the test tray TST.

The chamber unit 100 comprises a soak chamber 110 for applying the target high temperature or low temperature thermal stress to IC devices carried on a test tray TST, a test chamber 120 for bringing IC devices into contact with the test head 5 in a state applied thermal stress in the soak chamber 110, and an unsoak chamber 130 removing the applied thermal stress from the IC devices tested in the test chamber 120.

Note that the unsoak chamber 130 is preferably thermally insulated from the soak chamber 110 and the test chamber 120, actually a predetermined thermal stress is applied to the region of the soak chamber 110 and the test chamber 120, and the unsoak chamber 130 is thermally insulated from these. For convenience, these are referred to all together as the chamber unit 100.

The soak chamber 110, as shown in FIG. 2, is arranged to stick out upward relative to the test chamber 120. Furthermore, as shown schematically in FIG. 3, a vertical conveyance system is provided inside the soak chamber 110. A plurality of test trays TST stand by while being supported by the vertical conveyance system until the test chamber 120 is emptied. Mainly, while standing by, the IC devices are applied high temperature or low temperature thermal stress.

In the test chamber 120, a test head 5 is arranged at the its center. A test tray TST is conveyed above the test head 5 and the input/output terminals of the IC device are brought into electrical contact with the contact pins of the socket 50 of the test head 5 whereby the IC devices are tested.

In terms of the IC devices connected at one time to the test head 5, in the case of 64° C. devices arranged in 4 rows and 16 columns, for example, eight columns of IC devices are simultaneously tested every other column. That is, in the first test, the 32° C. devices arranged at every other column from the first column are connected to the sockets 50 of the test head 5 and tested and, in the second test, the test tray TST is moved by the amount of one column and the IC devices arranged at every other column from the second column are similarly tested so as to test all IC devices carried on the test tray TST. The test results are, for example, stored at addresses determined by the identification number attached to the test tray TST and the serial numbers of the IC devices assigned in the test tray TST.

The unsoak chamber 130, in the same way as the soak chamber 110, as shown in FIG. 2, is arranged to stick out upward relative to the test chamber 120 and, as shown schematically in FIG. 3, is provided with a vertical conveyance system. Furthermore, in this unsoak chamber 130, when applying a high temperature in the soak chamber 110, the IC devices are cooled by blown air so as to return to room temperature. On the other hand, when applying a low temperature in the soak chamber 110, the IC devices are heated by warm air or the heater etc. so as to return them to a temperature of an extent not causing condensation, then the unsoaked IC devices are carried out to the unloader unit 400.

To thermally insulate the soak chamber 110 and test chamber 120 and the unsoak chamber 130, a shutter 122 is provided between the test chamber 120 and the unsoak chamber 130.

This shutter 122, as shown in FIG. 11A and FIG. 11B, is designed to be opened and closed by the same double acting single rod type air cylinder 123 as the air cylinder 305 provided at the movable head 303 of the above-mentioned XY conveyance system 304. This air cylinder 123, in the same way as the above-mentioned air cylinder 305, is arranged so that the rod 123h is facing the downward direction.

While not particularly illustrated, the first hollow chamber 123d is connected to the air feed device 308 via the first feed system connected to the first port 123e, while the second hollow chamber 123f is connected to the air feed device 308 via the second feed system connected to the second port 123g. Note that the first feed system is an air feed system not provided with any element (for example a solenoid valve etc.) for closing that feed system when the electric power supply of the handler 1 is cut off. On the other hand, the second feed system is provided with a solenoid valve (not shown) able to be controlled to open and close by a control device 309 of the handler 1 and is an air feed system closed when the electric power supply of the handler 1 is cut off.

When using this air cylinder 123 to raise the shutter 122 (when closing the tray conveyance path 121), as shown in FIG. 11A, the solenoid valve is closed and the air feed to the second hollow chamber 123f via the second feed system is stopped. At this time, air is constantly fed to the first hollow chamber 123d via the first feed system, so the piston 123c rises inside the cylinder tube 123a. Along with this, the shutter 122 rises and closes the tray conveyance path 121.

On the other hand, when lowering the shutter 122 (when opening the tray conveyance path 121), as shown in FIG. 11B, the solenoid valve is opened and air is fed from the air feed device 308 to the second hollow chamber 123f via the second feed system. At this time, when the pressures of the air fed to the first and second hollow chambers 123d, 123f are substantially the same, the piston 123c descends inside the cylinder tube 123a by the difference of the pressure receiving areas at the top and bottom faces of the piston 123c. Along with this, the shutter 122 also descends and opens the tray conveyance path 121.

Furthermore, in the present embodiment, even when the electric power supply of the handler 1 is cut off, air is fed from the air feed device 308 to the first hollow chamber 123d via the first feed system. On the other hand, along with the electric power supply of the handler 1 being cut off, the solenoid valve closes, so the air feed to the second hollow chamber 123f via the second feed system is stopped. For this reason, even if the electric power supply of the handler 1 is cut off at the time of for example a power outage or emergency, the piston 123c automatically rises by the pressure in the first hollow chamber 123d, so the tray conveyance path 121 can be closed. Even if the electric power supply of the handler 1 suddenly is cut off, it is possible to thermally insulate the soak chamber 110 and test chamber 120 and the unsoak chamber 130.

Note that, as the air cylinder 123 of the XY conveyance system 304, it is also possible to provide a regulator at the first feed system for feeding air to the air cylinder 123 for raising and lowering the shutter. Due to this, it becomes possible to suitably regulate the thrust of the piston 123c.

An entrance 111 for carrying in the test trays TST from the apparatus base board 101 is formed at the top of the soak chamber 110. Also an exit (not shown) for carrying out the test trays TST to the apparatus base board 101 is formed at the top of the unsoak chamber 130. Further, the apparatus base board 101 is provided with a tray conveyance system 102 for transferring the test trays TST through the entrance 111 and the exit. For example, this tray conveyance system 102 comprises rotating rollers etc. The test tray TST carried out from the unsoak chamber 130 is returned to the soak chamber 110 via the unloader unit 400 and the loader unit 300 by the tray conveyance system 102.

The entrance 111 of the soak chamber 110 is provided with an openable and closable shutter 113 to thermally insulate the inside of the soak chamber 110 from the outside.

This shutter 113, as shown in FIG. 12A and FIG. 12B, can be opened and closed by a double acting single rod type air cylinder 112 similar to the air cylinder 305 provided at the movable head 303 of the XY conveyance system 304. This air cylinder 112 is arranged in a posture opposite to the air cylinder 305, that is, a posture where the rod 112 faces the top direction.

While not particularly illustrated, the first hollow chamber 112d is connected to the air feed device 308 via the first feed system connected to the first port 112e. On the other hand, the second hollow chamber 112f is connected to the air feed device 308 via the second feed system connected to the second port 112g. Note that the first feed system is an air feed system not provided with any element (for example, a solenoid valve etc.) for closing that feed system when the electric power supply of the handler 1 is cut off. On the other hand, the second feed system is provided with a solenoid valve (not shown) able to be controlled to open and close by the control device 309 of the handler 1 and is an air feed system closed when the electric power supply of the handler 1 is cut off.

When using this air cylinder 112 to lower the shutter 113 (when closing the entrance 111 of the soak chamber 110), as shown in FIG. 12A, the solenoid valve is closed and the air feed to the second hollow chamber 112f via the second feed system is stopped. At this time, air is being constantly fed to the first hollow chamber 112d via the first feed system, the piston 112c descends inside the cylinder tube 112a. Along with this, the shutter 113 descends and closes the entrance 111 of the soak chamber 110.

On the other hand, when raising the shutter 113 (when opening the entrance 111 of the soak chamber 110), as shown in FIG. 12B, the solenoid valve is opened and air is fed from the air feed device 308 to the second hollow chamber 112f via the second feed system. At this time, when the pressures of the air fed to the first and second hollow chambers 112d and 112f are substantially the same, the piston 112c rises inside the cylinder tube 112a by the difference of the pressure receiving areas at the top and bottom faces of the piston 112c. Along with this, the shutter 113 also rises and opens the entrance 111 of soak chamber 110.

Furthermore, in the present embodiment, even when the electric power supply of the handler 1 is cut off, air is fed from the air feed device 308 to the first hollow chamber 112d via the first feed system. Along with the electric power supply of the handler 1 being cut off, the solenoid valve closes, so the air feed to the second hollow chamber 112f via the second feed system is stopped. For this reason, for example, even if the electric power supply of the handler 1 is cut off at the time of for example a power outage or emergency, the piston 112c automatically descends by the pressure in the first hollow chamber 112d, so the entrance 111 of the soak chamber 110 can be closed. Even if the electric power supply of the handler 1 suddenly is cut off, the inside of the soak chamber 110 can be thermally insulated from the outside.

Note that, as the air cylinder 123 of the XY conveyance system 304, it is also possible to provide a regulator at the first feed system for feeding air to the air cylinder 112 for raising and lowering the shutter. Due to this, it becomes possible to suitably regulate the thrust of the piston 112c.

Note that, while not particularly illustrated, the exit of the unsoak chamber 130 is also provided with a shutter able to be raised or lowered by a double acting single rod type air cylinder. The first hollow chamber of that air cylinder is connected to the air feed device 308 via a first feed system. On the other hand, the second hollow chamber is connected to the air feed device 308 via a second feed system.

<Unloader Unit 400>

The unloader unit 400 is also provided with two XY conveyance systems 404 of the same structure as the XY conveyance system 304 provided at the loader unit 300. These XY conveyance systems 404 are used to reload the finished tested IC devices from a test tray TST carried out to the unloader unit 400 to customer trays KST in accordance with the test results.

While not particularly illustrated, the movable head 403 of this XY conveyance system 404 is also provided with a double acting single rod type air cylinder for raising or lowering the pickup head along the Z-axial direction. In the same way as the air cylinder 305 of the XY conveyance system 304, the first hollow chamber of the air cylinder is connected to the air feed device 308 via the first feed system. On the other hand, the second hollow chamber is connected to the air feed device 308 via the second feed system. Even if the electric power supply of the handler 1 is cut off, the movable head 403 will not descend and a collision with the apparatus base board 101 or other structures etc. and consequent breakage will be prevented.

As shown in FIG. 2, two pairs of windows 406 are formed at the apparatus base board 101 in the unloader unit 400 so that the customer trays KST carried into the unloader unit 400 arrange to approach the top surface of the apparatus base board 101.

Further, while not shown, elevator tables for raising and lowering the customer trays KST are provided below the windows 406. These carry customer trays KST filled with post-test IC devices and descend to transfer the full trays to the tray transfer arm 205.

Note that the embodiments explained above were described for facilitating the understanding of the present invention and were not described for limiting the present invention. Therefore, the elements disclosed in the embodiments include all design changes and equivalents falling under the technical scope of the present invention.

In the above embodiments, a double acting single rod type air cylinder was used so as to match the drive direction with the vertical direction, but the present invention is not particularly limited to this. The drive direction may also be matched with the horizontal direction.

Further, in the above embodiments, a cylinder driven by air pressure was explained, but the present invention is not particularly limited to this. For example, a hydraulic cylinder is also possible.

Further, in the above embodiments, the piston was movably inserted inside the cylinder tube along the vertical direction, but the present invention is not particularly limited to this. For example, the piston may also be inserted inside the cylinder tube so as to be movable along the horizontal direction.

Furthermore, in the above embodiments, the device system was explained as being applied to an electronic device test apparatus, but the present invention is not particularly limited to this. It may also be applied to systems other than electronic device test systems.

1. A movement apparatus configured to move a member, the movement apparatus comprising a fluid pressure cylinder having:
a cylinder tube;
a piston inserted inside the cylinder tube in a movable manner;
a first hollow chamber formed at one side of the piston;
a second hollow chamber formed at the other side of the piston and being larger than the first hollow chamber in terms of a pressure receiving area of the piston; and
a rod with one end coupled with the piston and another end coupled with the member, wherein
the first hollow chamber is connected to a fluid feed source via a first feed system configured to be able to constantly secure a fluid feed from the fluid feed source, and
the second hollow chamber is connected to the fluid feed source via a second feed system having a shutoff valve configured to be able to open and close a channel.

2. The movement apparatus as set forth in claim 1, wherein the first feed system has a regulating device configured to be able to regulate a flow rate or pressure of the fluid.

3. The movement apparatus as set forth in claim 1, wherein
the moving apparatus is provided in an electronic device test apparatus configured to test device under test for electrical characteristic,
the first feed system is able to ensure the fluid feed from the fluid feed source even when an electric power supply of the electronic device test apparatus is cut off, and
the shutoff valve of the second feed system includes a solenoid valve which drives by electric power fed from the electric power supply and closes the second feed system when the electric power supply is cut off.

4. The movement apparatus as set forth in claim 1, wherein the rod passes through the first hollow chamber and is coupled with the member at its other end.

5. The movement apparatus as set forth in claim 3, wherein the member is a holding part configured to hold a device under test by suction.

6. The movement apparatus as set forth in claim 3, wherein the member is a shutter configured to open and close a conveyance path inside the chamber or an opening part.

7. The movement apparatus as set forth in claim 5, wherein
the piston is inserted inside the cylinder tube so as to be able to move along the vertical direction,
the first hollow chamber is formed above or below the piston, and
the second hollow chamber is formed below or above the piston.

8. An electronic device test apparatus configured to bring input/output terminals of device under test into contact with a contact part of the test head so as to test the device under test for electrical characteristic, the electronic device test comprising the movement apparatus as set forth in claim 1.
